(19) United States
(12) Patent Application Publication
(10) Pub. No.: US 2025/0022971 A1
(43) Pub. Date: Jan. 16, 2025

(54) Solar Cell, Electrode Structure, Cell Module, Power Generation System and Preparation Method

(71) Applicants: ZHEJIANG AIKO SOLAR ENERGY TECHNOLOGY CO., LTD., Jinhua, Zhejiang (CN); ZHUHAI FUSHAN AIKO SOLAR ENERGY TECHNOLOGY CO., LTD., Zhuhai, Guangdong (CN); TIANJIN AIKO SOLAR ENERGY TECHNOLOGY CO., LTD., Tianjin (CN); GUANGDONG AIKO SOLAR ENERGY TECHNOLOGY CO., LTD., Foshan, Guangdong (CN)

(72) Inventors: Yongqian WANG, Jinhua, Zhejiang (CN); Wenli XU, Jinhua, Zhejiang (CN); Jianjun ZHANG, Jinhua, Zhejiang (CN); Gang CHEN, Jinhua, Zhejiang (CN)

(21) Appl. No.: 18/711,868

(22) PCT Filed: Mar. 13, 2023
(86) PCT No.: PCT/CN2023/081171

§ 371 Date: May 20, 2024

(30) Foreign Application Priority Data
Mar. 11, 2022 (CN) 202210239656.3

(51) Int. Cl. H01L 31/0224

(52) U.S. Cl. CPC H01L 31/022441; H01L 31/022466

(57) ABSTRACT

The present disclosure discloses an electrode structure of a solar cell, which belongs to the technical field of Photovoltaic (PV) cells and includes a conducting layer, and one end, configured to be connected to the solar cell, of the conducting layer is provided with a seed layer, and a width of the seed layer is less than that of the conducting layer. The present disclosure also discloses the solar cell, a cell module and a power generation system applying the electrode structure.

### CROSS-REFERENCE TO RELATED APPLICATION

The present disclosure claims priority to patent application No. 202210239656.3, filed on Mar. 11, 2022 and entitled “Solar Cell, Electrode Structure, Cell Module, Power Generation System and Preparation Method”, the disclosure of which is hereby incorporated by reference in its entirety.

### TECHNICAL FIELD

The present disclosure belongs to the technical field of Photovoltaic (PV) cells, and particularly relates to a solar cell, an electrode structure, a cell module, a power generation system and a preparation method.

### BACKGROUND

A solar cell, which is a photoelectric semiconductor chip capable of directly generating electricity by using sunlight, is also called a “solar chip” or a “PV cell”, and may instantaneously output voltage and generate current in a case of a loop as long as it is satisfied with a certain illumination condition. In physics, it is called solar PV (Photovoltaic, abbreviated as PV), PV for short.

At present, the structure of solar cells on the market is as shown in FIG. 1, including a substrate 1000. The substrate 1000 is provided with a conductive film layer 1001, but the structure easily results in the diffusion of material molecules in the conductive film layer 1001 into the substrate 1000, thereby forming a composite pair, resulting in photoelectric efficiency reduction.

### SUMMARY

The present disclosure provides the following technical solutions.

An electrode structure of a solar cell includes a conducting layer, and one end, configured to be connected to the solar cell, of the conducting layer is provided with a seed layer, a width of the seed layer is less than that of the conducting layer, and a predetermined surface of the conducting layer and the surface of the solar cell form a suspended structure, the predetermined surface is a surface of the conducting layer proximate to the seed layer and not covered by the seed layer.

In some embodiments, the seed layer is made of an alloy material, components of the seed layer include a functional component and a strengthening component, the functional component and the strengthening component being mixed in a certain ratio.

In some embodiments, the functional component is a metal having an average refractive index of less than 2 in the wavelength range of 850 nm-1200 nm.

In some embodiments, the functional component is one or more of AL, Ag, Cu and Mg, and the strengthening component includes one or more of Mo, Ni, Ti, W, Cr, Si, Mn, Pd, Bi, Nb, Ta, Pa and V, and content ratio of the functional component is >50%, and the content ratio of the functional component is a radio of content of the functional component to a total content, the total content is a sum of the content of the functional component and content of the strengthening component.

In some embodiments, the seed layer is prepared by one of Physical Vapor Deposition (PVD), screen printing, chemical vapor deposition, electroplating, or electroless plating.

In some embodiments, the conducting layer is made of a conductive metal, a main component of which is one or more of Cu, Ag and Al.

In some embodiments, the conducting layer is prepared by one of PVD, screen printing, chemical vapor deposition, electroplating, or electroless plating.

In some embodiments, the electrode structure of the solar cell further includes a protective layer provided on the surface of the conducting layer away from the seed layer, And the protective layer is prepared by Sn or Ag, and the protective layer is prepared by one of PVD, screen printing, chemical vapor deposition, electroplating, or electroless plating.

In some embodiments, a suspended average height of the suspended structure ranges from 10 nm-50 μm, and the suspended average height is a distance between the predetermined surface and the surface of the solar cell.

In some embodiments, the surface of the solar cell is also provided with a layer of dielectric film, the dielectric film is provided with an opening exposing a part of the surface of the solar cell, and the seed layer is locally in contact with the solar cell through the opening.

In some embodiments, a transparent conductive oxide film is also provided between the seed layer and the dielectric film, and a part of the transparent conductive oxide film is in contact with the solar cell through the opening provided in the dielectric film.

In some embodiments, the width of the seed layer=(20%-98%)*a width of the conducting layer.

In some embodiments, a width of the conducting layer−the width of the seed layer is >5 μm.

In some embodiments, the width of the seed layer=(30%-90%)*a width of the conducting layer.

In some embodiments, the width of the conducting layer−the width of the seed layer is >10 μm.

In some embodiments, the seed layer is formed by stacking a plurality of sub-seed layers.

In some embodiments, content of functional components of the sub-seed layers gradually decreases in a direction away from the solar cell.

In some embodiments, the thickness of the seed layer is 10 nm-1000 nm.

In some embodiments, the thickness of the conducting layer is 1-800 μm.

In addition, the present disclosure also discloses a solar cell, a solar cell module and a solar power generation system, all of which are based on the electrode structure mentioned in any one of the above solutions.

At the same time, the present disclosure also discloses a preparation method for preparing the electrode structure, which specifically includes the following steps:
1) a patterned mask layer is prepared on a solar cell;
2) a preparatory seed layer is prepared on a surface of the solar cell proximate to the patterned mask layer;
3) a conducting layer is prepared on a surface of the preparatory seed layer away from the solar cell;
4) a part of the preparatory seed layer not in contact with a substrate is removed using the patterned mask layer as a mask to obtain a seed layer, and the patterned mask layer is removed.

### BRIEF DESCRIPTION OF THE DRAWINGS

FIG. 1 is a schematic diagram of an overall structure in the related art.

FIG. 2 is a schematic diagram of an overall structure of an electrode structure according to the present disclosure.

FIG. 3 is a modeling comparison diagram of seed layers of different materials about light reflection according to the present disclosure.

FIG. 4 is a comparison diagram of diffusion coefficients of Cu and other metals.

FIG. 5 is a schematic diagram of electrode fall-off failure.

FIG. 6 is a schematic diagram of a connection structure of a main grid and a fine grid of a solar cell.

FIG. 7 is a schematic diagram of an existing electrode plating method.

FIG. 8 is a schematic diagram of an electrode plating method according to the present disclosure.

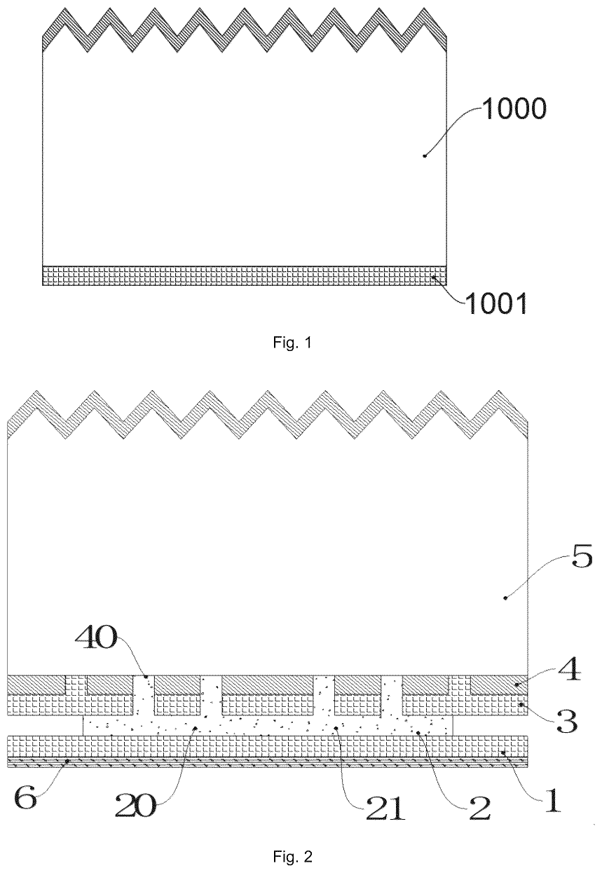

### DETAILED DESCRIPTION

The technical solutions in some embodiments of the present disclosure will be clearly and completely described in conjunction with the drawings in said embodiments of the present disclosure. It is apparent that the described embodiments are only a part of the embodiments of the disclosure, and not all of them.

### Embodiment

A solar cell is as shown in FIG. 2. In some embodiments, the solar cell is a back-contact solar cell. The back-contact solar cell includes a substrate 5. The substrate 5 is provided with an electrode structure.

The electrode structure includes a conducting layer 1. One end, configured to be connected to the substrate 5, of the conducting layer 1 is provided with a seed layer 2, the width of the seed layer 2 is less than that of the conducting layer 1, and a predetermined surface of the conducting layer and the surface of the solar cell form a suspended structure, the predetermined surface is a surface of the conducting layer proximate to the seed layer and not covered by the seed layer, that is to say, the part of the conducting layer 1 beyond the seed layer 2 and the surface of the solar cell form a suspended structure. Firstly, by guaranteeing that the width of the conducting layer 1 is greater than that of the seed layer 2, a low line resistance is achieved, at the same time, the risk of diffusion of molecules in the conducting layer 1 into the substrate 5 is avoided, and the photoelectric conversion efficiency of the cell is guaranteed. Secondly, the “suspended structure” is provided, and specifically in conjunction with the embodiment, an end surface of the conducting layer 1 facing the substrate 5 is provided on the substrate 5 at intervals, and the overall width of the conducting layer 1 is greater than that of the seed layer 2, so as to form an air layer and increase a light reflection effect, thereby improving the short circuit current of the solar cell and increasing the cell conversion efficiency.

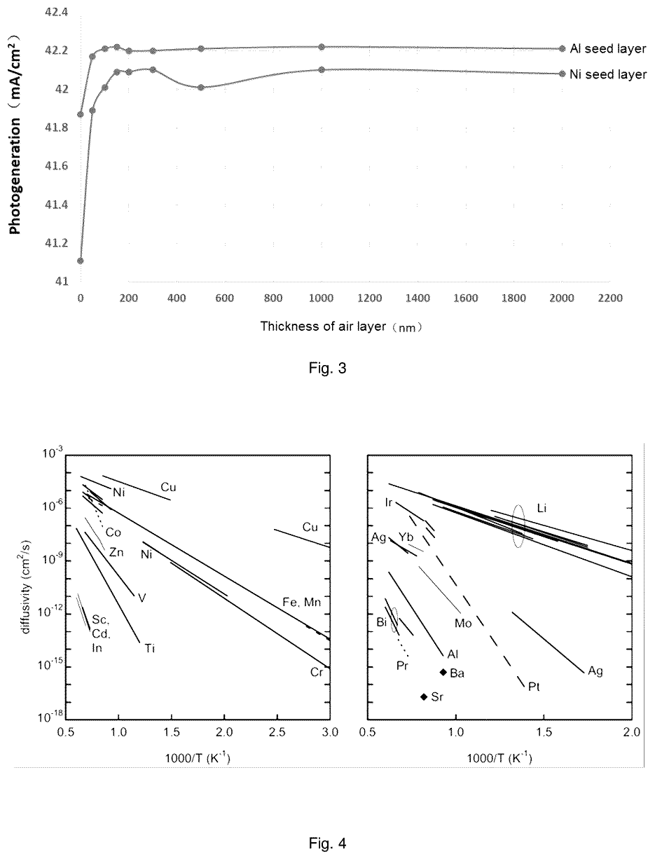

It is worth mentioning that, a suspended average height of the air layer ranges from 10 nm-50 μm, and the suspended average height is a distance between the predetermined surface and the surface of the solar cell. Referring to FIG. 3, a correlation between a light reflection condition and the suspended average height is shown. In the figure, as the thickness of the air layer gradually increases, the light reflection condition becomes better, until stable.

In some embodiments, the conducting layer 1 is made of a conductive metal, materials of the conducting layer include one or more of Cu, Ag and Al. The conducting layer 1 is prepared by one of PVD, screen printing, chemical vapor deposition, electroplating, or electroless plating, preferably, PVD.

It is to be noted that, the seed layer 2 is made of an alloy material, components of which include a functional component 20 and a strengthening component 21, the functional component 20 and the strengthening component 21 being mixed in a certain ratio. The functional component 20 is a metal material having an average refractive index of less than 2 in the wavelength range of 750 nm-1250 nm. An effect of back reflection is enhanced by the functional component 20, and an adhesion effect of the conducting layer 1 and the substrate 5 is enhanced by the strengthening component 21. In some embodiments, the functional component 20 is one or more of AL, Ag, Cu and Mg, and the strengthening component 21 includes one or more of Mo, Ni, Ti, W, Cr, Mn, Pd, Bi, Nb, Ta, Pa, Si and V. The functional component is >50% according to content ratio, that is, content ratio of the functional component is >50%, and the content ratio of the functional component is a radio of content of the functional component to a total content, the total content is a sum of the content of the functional component and content of the strengthening component.

The seed layer is prepared by one of PVD, screen printing, chemical vapor deposition, electroplating, or electroless plating, preferably, PVD.

In addition, the electrode structure further includes a protective layer 6 provided on the conducting layer 1 away from the seed layer. The protective layer 6 is prepared by Sn or Ag, and the protective layer 6 is prepared by one of PVD, screen printing, chemical vapor deposition, electroplating, or electroless plating. In some embodiments, the protective layer 6 is prepared by electroplating or electroless plating with Sn, and the function thereof is to protect the conducting layer 1 from oxidation by means of an Sn layer, and at the same time to improve the connection strength with a solder strip during subsequent assembly of a cell module.

In order to further elaborate the electrode structure, a description is made in conjunction with a preparation process thereof. The preparation process includes the following steps.
1) A patterned mask layer is prepared on the substrate 5 (the mask layer will be removed in post-processing, therefore, not shown in the figure) by any one of two methods, namely, a hard mask plate and laser etching. For the explanation of the hard mask plate, reference may be made to the description in Chinese patent application No. 2021116201937.
2) The seed layer 2 is prepared on the basis of S1). The thickness of the seed layer 2 is 10 nm-1000 nm, and the seed layer 2 may be of a single layer structure, or may be formed by stacking a plurality of sub-seed layers. When the seed layer 2 is formed by stacking the plurality of sub-seed layers, the content of the functional components 20 of the sub-seed layers stacked away from the substrate 5 gradually decreases.

Specifically, when a multilayer structure is selected, the reason why the content of the functional component 20 is gradually changed mainly lies in that the above functional component 20 may enhance the light reflection effect, but may not improve the connection strength of the conducting layer 1 provided on the substrate 5, and as the content of the functional component 20 gradually decreases, the strengthening component 21 gradually increases, but the content ratio of the functional component 20 is controlled to be >50% as a whole, so as to enhance the connection strength of the conducting layer 1 provided on the substrate 5.
3) The conducting layer 1 is prepared on a surface of the seed layer 2 away from the solar cell. The conducting layer has a thickness of 1-800 μm and is prepared by PVD.
4) The seed layer 2 not covered with the conducting layer 1 and the patterned mask layer are removed.

It is to be noted that, in some embodiments, the width of the seed layer 2 is 10%-90% of the width of the conducting layer 1, and the width of the conducting layer 1−the width of the seed layer 2 is >10 μm.

In another embodiment, the width of the seed layer 2=(30%-90%)*the width of the conducting layer 1. The width of the conducting layer 1−the width of the seed layer 2 is >10 μm.

At present, Ag paste is used as an electrode material in mass-produced crystalline silicon solar cells. The cost of the Ag paste accounts for nearly 30% of the non-silicon cost of the cell. Production technologies that reduce the amount of Ag or do not use Ag will effectively reduce the production cost of the solar cell. Cu is a good substitute for Ag, and the advantages of Cu compared with Ag as a conductive material are shown in the following Table a:

TABLE a

| Metal | Ag | Cu |
|---|---|---|
| Body resistivity | 1.60E−06 | 1.70E−06 |
| (ohm · cm) | | |
| Price (yuan/ton) | 5101000 | 70970 |

It may be seen from Table a that, Cu has relatively stable chemical properties, excellent ductility, sufficiently low body resistivity, and the excellent properties of being widely available and inexpensive (close to 1/72 of the price of an Ag material), so that Cu becomes an effective substitute for Ag. However, the application of Cu in the solar cell is limited by two important features. The first one is that a diffusion coefficient of Cu is too large. FIG. 4 is a schematic diagram of diffusion coefficients of common metals. The horizontal and vertical coordinates in FIG. 4 respectively represent a reciprocal of temperature (in Kelvin K) and the diffusion coefficients of metal elements. It may be seen from FIG. 4 that the diffusion coefficient of Cu is much higher than that of other metals, which is >5 orders of magnitude higher than that of Ag/Al.

The second is that the defects of Cu have a larger trapping cross-section for a hole, which may greatly reduce the minority carrier lifetime and thus reduce the electrical performance of the solar cell. The influence of the content of Cu on the minority carrier lifetime and the performance of the cell is shown in the following Table b:

TABLE b
3 ohm · cm n-type silicon wafer

| | Body | Influence |
|---|---|---|
| Content | minority | on cell |
| of Cu | carrier | efficiency |
| (1/cm3) | lifetime@1E15 | (%) |
| 0 | 33.25 | — |
| 1.00E+12 | 15.15 | −0.29 |
| 5.00E+12 | 4.48 | −1.35 |
| 1.00E+13 | 2.35 | −2.28 |
| 1.50E+13 | 1.49 | −2.81 |

It may be seen from Table b that, as the content of Cu increases, the body minority carrier lifetime is greatly reduced and the battery efficiency is also greatly reduced. Even with only 1E12/cm3 of Cu impurities, the cell efficiency is reduced by 0.29%.

In the related art, Ni (nickel) is generally used as a barrier layer for Cu diffusion, and a substrate and a Cu electrode may be bonded well at the same time. An implementation scheme thereof is generally as follows: preparation of the substrate after coating-laser film opening-Ni electroplating-Cu layer electroplating. However, during the study, we found that Ni as the barrier layer of Cu had a large defect of low long-band reflection effect to reduce the light trapping effect of the cell and further reduce the cell conversion efficiency.

Comparison data of optical properties of Ni+Cu and Ag as electrode materials is shown in the following Table c:

TABLE c

| | Short Circuit Current of cell | |
|---|---|---|
| | (J_{sc}/cm²) | |
| | | Optical |
| | Experimental | simulation |
| | result | result |
| Ag Electrode Route | 42.09 | 42.12 |
| Ni + Cu | 40.73 | 41.37 |

It may be seen from Table c that, the combination of Ni+Cu greatly reduces the short circuit current of the cell. The simulation result predicts that the density of the short circuit current may be reduced by 0.75 mA/cm2, and the experimental result reduces the density of the short circuit current by 1.36 mA/cm2, which is greater than the theoretical prediction.

The light trapping effect of common metals is analyzed below.

At present, the thickness of a silicon wafer of a finished cell is about 150 μm, and light with the wavelength of >850 nm may effectively penetrate this thickness. The band gap of Tongsihai Si is 1.12 eV, so that the light with the wavelength of >1200 nm is difficult to excite an electron-hole pair. Therefore, when considering the light trapping effect, the 850-1200 nm band is mainly concerned. Table d below shows the interface reflectivity of different metals and the market price found in February 2022:

TABLE d

| | Simulation | | |
|---|---|---|---|
| | result of | | |
| | average | | |
| | interface | | |
| | reflectivity | | |
| | of silicon | | |
| | and | | Simulation |
| | materials at | | result of |
| | 850-1200 nm | | short circuit |
| | band | Price | current |
| Material | (%) | (Yuan/ton) | (mA/cm²) |
| Ag | 96.6 | 5,101,000 | 42.18 |
| Al | 80.7 | 22,800 | 42.04 |
| Cu | 91.6 | 70,970 | 42.09 |
| Mg | 80.2 | 50,800 | 41.91 |
| Cr | 22.3 | 67,100 | 41.17 |
| Mo | 33.2 | 370,000 | 41.29 |
| Ni | 38.8 | 180,200 | 41.35 |
| Sn | 51.9 | 339,000 | 41.52 |
| Ti | 18.1 | 80,000 | 41.17 |
| W | 21.6 | 171,500 | 41.20 |

It may be seen from Table d that, there is a great difference in the interface reflectivity between different metals, and Ag/Al/Cu/Mg four metals may obtain relatively ideal short circuit current results, which may form an effective light trapping effect in the seed layer 2. Further analysis is that: Cu may not be used as the seed layer 2 due to the fact that an important function of the seed layer 2 is to block Cu; the chemical property of Mg is too active and is not a good choice; the price of Ag is higher and it is not a good choice; and Al is an ideal metal of the seed layer 2, which has excellent back reflectivity, is relatively stable in chemical properties, and is inexpensive, only 1/223 of Ag and ⅓ of Cu.

However, the Al metal alone as seed layer 2 introduces another problem that: the adhesion between Al and other metals is weak. A technology using Al only as the seed layer 2 may make the reliability of a product not meet the standard. The Al may be separated from the outer metal due to alternate cooling and heating or bending of a product, or the stress of a welding spot in module welding, resulting in falling off and failure.

The bonding force between Al and Cu is poor, and fragmented grid lines easily fall off. In order to solve this problem, several improved methods have been tried, such as increasing an Al/substrate contact area, increasing the temperature of a sample to promote the diffusion between the metals, inserting new materials such as TiW between Al/Cu materials, etc. Finally, it was found that if the strengthening component forming a good interconnection with Cu was directly added to the Al material as the seed layer 2, no additional annealing treatment was even required after Cu electroplating, namely, a good seed layer 2/conducting layer 1 cross-connection was formed, thereby greatly improving the adhesion of the conducting layer 1, and finally solving this problem.

In further verification, the strengthening component 21 such as Mo, Ni, Ti, W, Cr, Mn, Pd, Bi, Nb, Ta, Pa, Si and V play a significant adhesion promotion effect.

Furthermore, it may be seen from Table d that, Mo, Ni, Ti, W, Cr, Mn, Pd, Bi, Nb, Ta, Pa, Si and V materials have a low reflectivity, and if they are added too much, the optical properties may be reduced. Taking W as an example, we simply assumed that the properties of the alloy components were strengthened average values of the components, and calculation results shown in Table e below were obtained.

TABLE e

| W | Short Circuit |
|---|---|
| Content | Current |
| ratio | of cell |
| (%) | (J_{sc}/cm²) |
| 100 | 40.8 |
| 90 | 40.92 |
| 80 | 41.04 |
| 70 | 41.16 |
| 60 | 41.28 |
| 50 | 41.4 |
| 40 | 41.52 |
| 30 | 41.64 |
| 20 | 41.76 |
| 10 | 41.88 |
| 0 | 42.00 |

When the content of W is 30%, the current loss is 0.36 mA/cm2, which causes a decrease in the cell conversion efficiency of about 0.2%. Although this is relatively large, it is acceptable in view of the decrease in the cost associated with the comprehensive replacement of Ag by Cu and the solution to the reliability problem, and therefore it is considered that ≤30% of the strengthening component is a recommended value.

Further, a ratio of the strengthening components 21 in the seed layer 2 may be unevenly distributed, so that a better performance effect is obtained on a principle that: the part close to the substrate 5 reduces the content of the strengthening component 21, so that the reflection of light may be enhanced, and the part in contact with the metal of the conducting layer 1 may relatively contain a higher strengthening component to improve the bonding force with the metal of the conducting layer.

Table f below is a comparison of welding tension of different electrode technologies:

TABLE f

| | Welding |
|---|---|
| | tension |
| Electrode technology | (N/mm) |
| Conventional Ag electrode | 1.3 |
| Al + Cu electrode | 0.2 |
| Al + TiW + Cu electrode | 0.5 |
| Al alloy + Cu electrode in this patent | 1.7 |

It may be seen from the Table f that the tension of the grid line of the pure Al seed layer 2 is lower, much lower than that of the conventional Ag electrode, while the welding tension is improved after Al and Cu are directly inserted into a TiW material, but there is still a deficiency. The welding tension of the solar cell made of the Al alloy seed layer 2 in the present disclosure is even higher than that of the conventional Ag electrode.

With Al as the main component, the adhesion of the seed layer to the Cu conducting layer and the light trapping effect of the solar cell are promoted. Table g lists data of the technical effects that each individual strengthening component may bring in combination with the main component Al:

TABLE g

| | | | | Cell | |
|---|---|---|---|---|---|
| | | | | conversion | |
| Material of seed | | Tension | | efficiency | Efficiency |
| layer | | N/mm | Tension determination | (%) | determination |
| Conventional Ag | | 1.3 | / | 25.43 | / |
| electrode | | | | | |
| Al | | 0.2 | Too low to meet | 25.62 | / |
| | | | reliability requirement | | |
| Al alloy | W | 1.7 | Significant | 25.52 | Efficiency loss |
| seed | | | improvement compared | | <0.3%, as expected |
| layer | | | with pure Al | | |
| | Ti | 1.2 | significant improvement | 25.47 | Efficiency loss |
| | | | compared with pure Al | | <0.3%, as expected |
| | Mo | 1.4 | Significant | 25.49 | Efficiency loss |
| | | | improvement compared | | <0.3%, as expected |
| | | | with pure Al | | |
| | Ni | 1.5 | Significant | 25.56 | Efficiency loss |
| | | | improvement compared | | <0.3%, as expected |
| | | | with pure Al | | |
| | Si | 1.1 | Significant | 25.42 | Efficiency loss |
| | | | improvement compared | | <0.3%, as expected |
| | | | with pure Al | | |
| | Cr | 0.9 | Significant | 25.44 | Efficiency loss |
| | | | improvement compared | | <0.3%, as expected |
| | | | with pure Al | | |
| | Ta | 2.1 | Significant | 25.39 | Efficiency loss |
| | | | improvement compared | | <0.3%, as expected |
| | | | with pure Al | | |
| | Mn | 0.7 | Significant | 25.57 | Efficiency loss |
| | | | improvement compared | | <0.3%, as expected |
| | | | with pure Al | | |
| | Pd | 0.9 | Significant | 25.38 | Efficiency loss |
| | | | improvement compared | | <0.3%, as expected |
| | | | with pure Al | | |
| | Bi | 0.8 | Significant | 25.47 | Efficiency loss |
| | | | improvement compared | | <0.3%, as expected |
| | | | with pure Al | | |
| | Nb | 0.6 | Significant | 25.34 | Efficiency loss |
| | | | improvement compared | | <0.3%, as expected |
| | | | with pure Al | | |
| | Pa | 1 | Significant | 25.39 | Efficiency loss |
| | | | improvement compared | | <0.3%, as expected |
| | | | with pure Al | | |
| | V | 1.7 | Significant | 25.48 | Efficiency loss |
| | | | improvement compared | | <0.3%, as expected |
| | | | with pure Al | | |

It may be seen from the above experimental data that Cr, Mn, Pd, Bi, Nb, Ta, Pa, Si and V as the strengthening components may also improve the adhesion of the seed layer and the Cu conducting layer and the light trapping effect of the solar cell. It should be emphasized that there are hundreds of combinations of any one or more of the strengthening components Mo, Ni, Ti, W, Cr, Mn, Pd, Bi, Nb, Ta, Pa, Si and V in combination with Al, and it is impossible to provide the experimental comparison data of all the compositions. Therefore, on the premise that the experimental data of Ni, Mo, Ti, W, Cr, Mn, Pd, Bi, Nb, Ta, Pa, Si and V as the single strengthening components is given in the specific implementation modes, it is clear and apparent that other strengthening components in combination with the main component Al may also achieve the desired technical effect.

Further, the thickness of the seed layer 2 is preferably ≥30 nm, and experiments found that the seed layer 2 with a thickness of 30 nm was sufficient to block the diffusion of Cu metal, while the main consideration for the thickness of ≤300 nm was cost control, for example, the seed layer 2 was prepared by using a PVD method, even if the price of Al was lower than that of other metals, the cost influence of an Al target was still not ignored, the higher the thickness of the seed layer 2, the lower the device side productivity, which is not conducive to the promotion of mass production. Therefore, the thickness of the seed layer is preferably between 30-300 nm.

Furthermore, in order to save the cost of the alloy target and further limit the diffusion of the Cu metal towards the substrate, a layer of transparent conductive oxide film 3 may be added between the alloy seed layer 2 and the substrate 5. Light in a long band may penetrate through the transparent conductive oxide film 3 and perform effective reflection at the interface of the seed layer 2, and the deal performance and reliability results may also be obtained.

In addition, the surface of the substrate 5 is also provided with a layer of dielectric film 4, the dielectric film 4 is provided with an opening 40, and the seed layer 2 is locally in contact with the substrate 5 through the opening 40.

The seed layer 2 forms a conductive contact with the substrate 5 through the opening 40, which solves the contradiction between the electrode width and the damage of film opening is solved, so that the electrode width may be greatly increased, on the one hand, the line resistance of the solar cell is reduced, and on the other hand, the problem that the grid line easily falls off due to the too narrow line width of the electroplating electrode for a long time is solved. In addition, streamlined electroplating is performed on a solar cell to be electroplated that has completed the growth of the seed layer 2 through a self-developed horizontal electroplating device, which solves the problem in the related art that electroplating in a vertical electroplating manner has low efficiency and is not suitable for large-scale electroplating.

In order to facilitate a better understanding of the beneficial effects of the present disclosure, the performance improvement of the solar cell brought by the present disclosure is evaluated by a modeling calculation, as shown in Table h below for details:

TABLE h
Thickness of electroplated layer: 6 um size of silicon wafer:
210 size loss at laser film opening place: 100 fA/cm2

| | | Electrode | | Front | | | | |
|---|---|---|---|---|---|---|---|---|
| | | resistance | | current | | | | |
| | Electrode | value | Corresponding | loss | Corresponding | Composite | Corresponding | Total |
| | width | (ohm · | efficiency | value | efficiency | J0 | efficiency | loss |
| | (um) | cm²) | loss (%) | (J_{sc}/cm²) | loss (%) | (fA/cm²) | loss (%) | (%) |
| Related | 30 | 0.414 | 0.66 | 0.9 | 0.54 | 4.3 | 0.12 | 1.3 |
| art | 50 | 0.239 | 0.38 | 1.5 | 0.90 | 7.1 | 0.2 | 1.5 |
| | 100 | 0.116 | 0.18 | 3 | 1.80 | 14.3 | 0.37 | 2.4 |
| | 150 | 0.077 | 0.12 | 4.5 | 2.69 | 21.4 | 0.54 | 3.4 |
| | 200 | 0.057 | 0.09 | 6 | 3.59 | 28.6 | 0.69 | 4.4 |
| | 300 | 0.038 | 0.06 | 9 | 5.39 | 42.9 | 0.96 | 6.4 |
| Solution | 300 | 0.038 | 0.06 | 0 | 0 | 4.3 | 0.12 | 0.2 |
| of this | | | | | | | | |
| patent | | | | | | | | |

It may be seen from Table h that, in the existing solution, as the electrode width increases, the loss of electrode resistance gradually decreases, but the efficiency loss caused by front shading and composition gradually increases, which forms a contradiction. Finally, it is concluded that the smaller the electrode width, the smaller the loss, but the efficiency loss has reached 1.3% even when the electrode width is reduced to 30 μm. At the same time, insufficient adhesion of the grid lines at this width may lead to serious reliability problems, which is an important reason why the electroplating technology has not been applicable to mass production.

However, the present disclosure solves the contradiction in the related art: 1) a back-contact battery structure with no electrode on the front side is used to solve the shading loss of the electrode; 2) PVD is used to realize the seed layer 2, so that the electrode width may be larger than the film opening size, and the ideal electrode width may be obtained under the condition of greatly reducing the laser damage; and 3) the electrode is sufficiently wide (the width is preferably >30 μm, more preferably, the width range is 80-400 μm) to greatly increase the adhesion between the electrode and the seed layer 2 and between the seed layer 2 and the substrate 5.

For the influence of the electrode width on the adhesion and reliability, the following is emphatically explained.

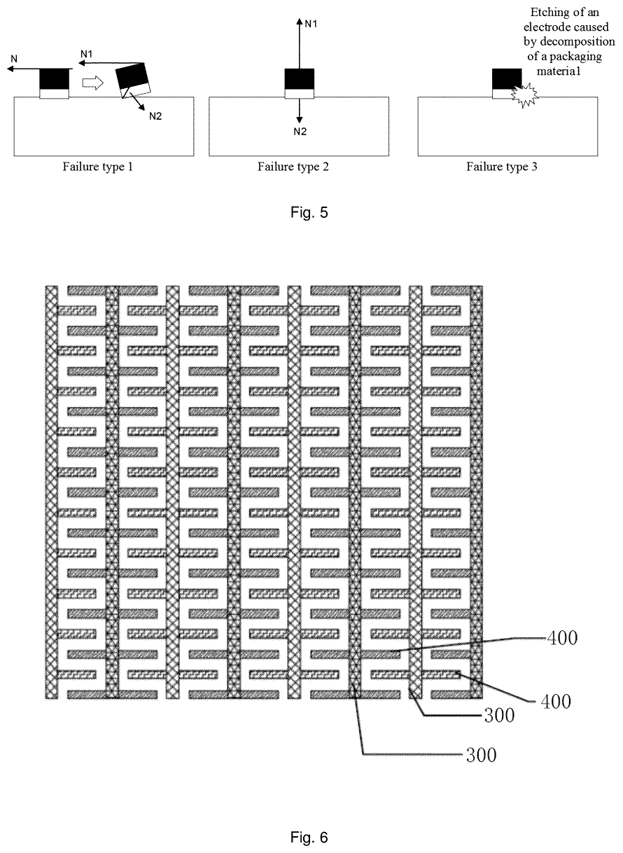

Referring to FIG. 5, three main mechanisms for electrode fall-off failure are as follows.
1) A failure type 1 is transverse shear. N1 in FIG. 6 represents an external force and N2 represents an adhesion, and the greater the electrode width, the smaller the difference in moment arm between N2 and N1, so that the failure risk of this type may be reduced.
2) A failure type 2 is vertical tension. The larger the electrode width, the larger the bonding area and thus the greater the adhesion, so that the failure risk of this type may be reduced.
3) A failure type 3 is etching of the electrode by water vapor caused by the decomposition of a packaging material of a solar cell module. Ni, Mo, Ti, etc. are more active than Cu, especially the acidic decomposition gradually etches the seed layer during long-term aging, and the electrode width is too narrow, which may affect the long-term aging performance of the product.

Another important factor limiting the mass production of existing electroplating technologies is: too low productivity, poor uniformity, poor appearance/performance of an electrode clamping area, which is explained below.

Existing technical solutions require laser film opening beneath the electrode to expose the area to be electroplated and then connect a cathode to the film perforation region, so that the substrate forms the cathode of an electroplating system, which has the following problems.

As shown in FIG. 6, four wide electrodes 300 standing across the entire cell are referred to as main grids, and fine electrodes 400 between the main grids are referred to as fine grids. The main grid takes the role of collecting the current collected by the fine grid and welding with the welding strip, so that a larger width is required. The laser damage in this area is not acceptable if a laser film opening+plating manner is used, so that some researchers have compromised the option of using the Ag paste for the main grid and electroplating for the fine grid, but the cost reduction is limited because the Ag paste is still used.

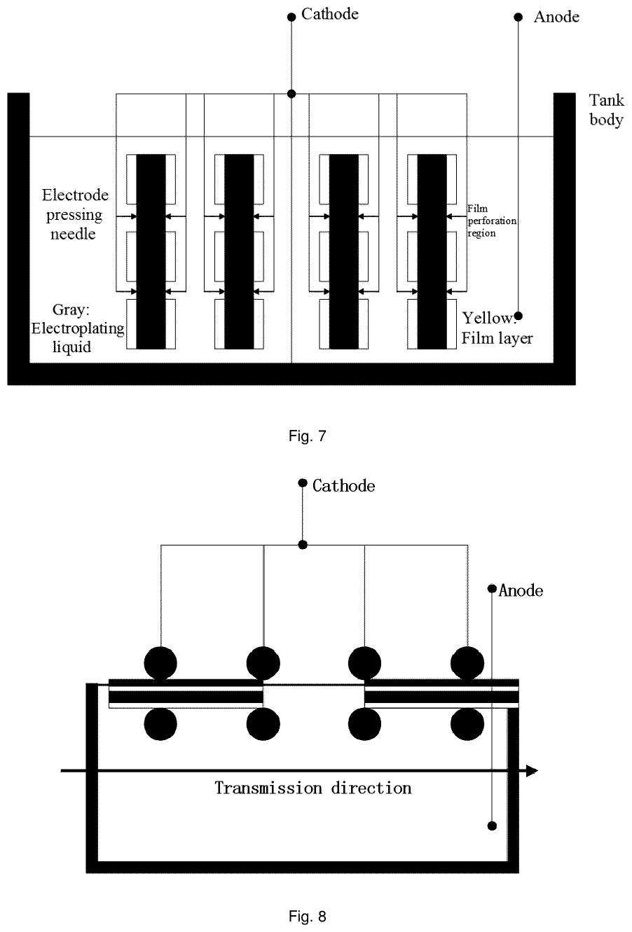

An existing method for electroplating an electrode for a solar cell is as shown in FIG. 7. A cathode clamp needs to hold the solar cell (where a pressing needle is in contact with a specially designed film perforation region), and then the cell is immersed in a plating tank with a seed layer being Ni. After Ni plating, same is lifted to a water tank for cleaning after passing through a cleaning tank. After cleaning, same is lifted to an electroplating Cu tank for Cu electroplating. Then same is lifted to the water tank for cleaning, and then is lifted to an Sn tank for Sn plating. In order to ensure the stability of clamping and relatively small stress, the area of an electrode piezoelectric place needs to be large enough, which leads to regional laser damage loss and affect the appearance of the product. Since the poor conductivity of the substrate of the silicon wafer leads to surface potential non-uniformity to affect the electroplating uniformity within the cell, in order to make up this problem, it is often necessary to provide a plurality of electrode pressing needles on the single cell, which further deteriorates the above-mentioned influence. Because the positions of the tanks in different areas of the single cell and between different cells are not consistent, there are differences in the concentration of chemical names on the surface of the single cell, which causes differences in the electroplating thickness within the product cell and between the cells. In addition, limited and mechanical structures limit the number of cells that may be clamped in the single tank, which has limited capacity and is difficult to support mass production.

However, in the present disclosure, the implementation scheme of electrode plating is as shown in FIG. 8, the seed layer 2 grows on the back side of the cell, and a growth manner of the seed layer 2 preferably uses a PVD technology. The seed layer 2 may be partly removed after electroplating or before electroplating, but at least during plating, the seed layer 2 still covers >20% of the total area. At this time, the seed layer is located on the outermost surface of the back side of the cell, so that the seed layer 2 is fully in good contact with the cathode. Then, the cell is transported in a horizontal chain in the plating bath, where rollers rotate to drive the cell to move, and the rollers at one side are made of the conductive material to form a cathode of the plating system. The cell keeps continuous or nearly continuous contact with the cathode rollers during horizontal transport to realize electroplating. The use of the above electrode electroplating method has the following advantages. 1) Only a bath body with a suitable length needs to be designed to improve the transmission speed, so that the ideal cell yield per unit time may be realized to meet the demand for mass production; 2) the conductivity of the seed layer is high, and at the same time, the surface of the cell is in uniform contact with liquid medicine, so that the uniformity and stability of the electroplating process are improved; and 3) the laser film perforation region is independent of the electrode width, and no additional laser film opening is needed in the main grid area and the cathode contact area, so that the laser loss is effectively reduced.

From the above description, a person skilled in the art may clearly know that the main beneficial effects of the present disclosure are that: large-area deposition of the seed layer and horizontal electroplating are organically combined, if the existing technology of electroplating the seed layer 2 is used, a good contact with the cathode rollers may not be formed, resulting in that horizontal electroplating may not be applied to solar cell manufacturing; and if the existing vertical electroplating technology is used in the process based on the large-area seed layer 2, the electroplating technology is difficult to realize large-scale promotion due to the problems of stability, uniformity and low productivity.

Further, if the area under the battery electrode adopts a passivation contact technology, namely. growth of a tunneling oxide layer+a polysilicon passivation layer, a more ideal effect may be obtained. The reasons are that: 1) the seed layer grown by PVD (especially sputtering) is easy to cause bombardment damage on the surface, while the passivation contact structure on the surface of the substrate may effectively resist the bombardment damage; and 2) the passivation contact structure may effectively reduce the laser film opening damage. Therefore, the passivation contact structure and the PVD seed layer+horizontal electroplating technology are organically combined, which effectively solves the negative effects of the PVD seed layer+horizontal electroplating technology.

In the description of the present disclosure, it is to be understood that, the orientations or positional relationships indicated by the terms “center”, “transverse”, “upper”, “down”, “left”, “right”, “vertical”, “horizontal”, “top”, “bottom”, “inside”, “outside”, etc. are based on the orientations or positional relationships shown in the drawings, and are only for the convenience of describing the present disclosure and simplifying the description. The description does not indicate or imply that the device or element referred to must have a specific orientation, be constructed and operated in a specific orientation, and therefore cannot be construed as limiting the present disclosure. In addition, the terms “first” and “second” are used for descriptive purposes only, and cannot be understood as indicating or implying relative importance. Therefore, the features defined with “first” and “second” may explicitly or implicitly include one or more features. In the description of the present disclosure, “plurality” means at least two or more than two, unless otherwise specifically defined. In addition, the term “include” and any transformations thereof are intended to cover nonexclusive inclusions.

The present disclosure is explained according to the embodiments. The apparatus may also make a number of variations and modifications without departing from the conception of the present disclosure. It is to be noted that, the technical solutions obtained by equivalent substitutions or equivalent transformations shall fall within the scope of protection of the present disclosure.

What is claimed is:

1. An electrode structure of a solar cell, comprising a conducting layer, wherein one end, configured to be connected to the solar cell, of the conducting layer is provided with a seed layer, a width of the seed layer is less than that of the conducting layer, and a predetermined surface of the conducting layer and the surface of the solar cell form a suspended structure, the predetermined surface is a surface of the conducting layer proximate to the seed layer and not covered by the seed layer.

2. The electrode structure of the solar cell according to claim 1, wherein the seed layer is made of an alloy material, components of the seed layer comprise a functional component and a strengthening component, the functional component and the strengthening component being mixed in a certain ratio.

3. The electrode structure of the solar cell according to claim 2, wherein the functional component is a metal having an average refractive index of less than 2 in the wavelength range of 850 nm-1200 nm.

4. The electrode structure of the solar cell according to claim 3, wherein the functional component is one or more of AL, Ag, Cu and Mg, and the strengthening component comprises any one or more of Mo, Ni, Ti, W, Cr, Si, Mn, Pd, Bi, Nb, Ta, Pa and V, wherein content ratio of the functional component is >50%, and the content ratio of the functional component is a radio of content of the functional component to a total content, the total content is a sum of the content of the functional component and content of the strengthening component.

5. The electrode structure of the solar cell according to claim 2, wherein the seed layer is prepared by one of Physical Vapor Deposition (PVD), screen printing, chemical vapor deposition, electroplating, or electroless plating.

6. The electrode structure of the solar cell according to claim 1, wherein the conducting layer is made of a conductive metal, materials of the conducting layer comprise one or more of Cu, Ag and Al.

7. The electrode structure of the solar cell according to claim 6, wherein the conducting layer is prepared by one of PVD, screen printing, chemical vapor deposition, electroplating, or electroless plating.

8. The electrode structure of the solar cell according to claim 1, the electrode structure further comprising a protective layer provided on the surface of the conducting layer away from the seed layer, wherein the protective layer is prepared by Sn or Ag, and the protective layer is prepared by one of PVD, screen printing, chemical vapor deposition, electroplating, or electroless plating.

9. The electrode structure of the solar cell according to claim 1, wherein a suspended average height of the suspended structure ranges from 10 nm-50 μm, and the suspended average height is a distance between the predetermined surface and the surface of the solar cell.

10. The electrode structure of the solar cell according to claim 8, wherein the surface of the solar cell is also provided with a layer of dielectric film, the dielectric film is provided with an opening exposing a part of the surface of the solar cell, and the seed layer is locally in contact with the solar cell through the opening.

11. The electrode structure of the solar cell according to claim 10, wherein a transparent conductive oxide film is also provided between the seed layer and the dielectric film, and a part of the transparent conductive oxide film is in contact with the solar cell through the opening provided in the dielectric film.

12. The electrode structure of the solar cell according to claim 1,
wherein the width of the seed layer=(20%-98%)*a width of the conducting layer,
or, a width of the conducting layer−the width of the seed layer is >5 μm,
or, the width of the seed layer=(30%-90%)*a width of the conducting layer,
or the seed layer is formed by stacking a plurality of sub-seed layers.

13. (canceled)

14. (canceled)

15. The electrode structure of the solar cell according to claim 12, wherein the width of the conducting layer−the width of the seed layer is >10 μm.

16. (canceled)

17. The electrode structure of the solar cell according to claim 12, wherein content of functional components of the sub-seed layers stacked gradually decreases in a direction away from the solar cell.

18. The electrode structure of the solar cell according to claim 1, wherein the thickness of the seed layer is 10 nm-1000 nm.

19. The electrode structure of the solar cell according to claim 11, wherein the thickness of the conducting layer is 1-800 μm.

20. A solar cell, comprising the electrode structure according to claim 1.

21. A solar cell module, comprising the solar cell according to claim 20.

22. A solar power generation system, comprising the solar cell module according to claim 21.

23. A preparation method of an electrode structure, comprising:
1) preparing a patterned mask layer on a solar cell;
2) preparing a preparatory seed layer on a surface of the solar cell proximate to the patterned mask layer;
3) preparing a conducting layer on a surface of the preparatory seed layer away from the solar cell; and
4) removing a part of the preparatory seed layer not in contact with a substrate using the patterned mask layer as a mask to obtain a seed layer, and removing the patterned mask layer.
